(19) United States
(12) Patent Application Publication
(10) Pub. No.: US 2021/0406769 A1
(43) Pub. Date: Dec. 30, 2021

(54) INFORMATION PROCESSING SYSTEM AND COMPRESSION CONTROL METHOD

(71) Applicant: Hitachi, Ltd., Tokyo (JP)

(72) Inventors: Katsuto SATO, Tokyo (JP); Hiroaki AKUTSU, Tokyo (JP)

(73) Assignee: Hitachi, Ltd.

(21) Appl. No.: 17/352,016

(22) Filed: Jun. 18, 2021

(30) Foreign Application Priority Data
Jun. 25, 2020 (JP) 2020-109384

(51) Int. Cl. G06N 20/00; H03M 7/30

(52) U.S. Cl. CPC G06N 20/00; H03M 7/60

(57) ABSTRACT

A dynamic driving plan generator generates a driving plan representing a dynamic partial driving target of a compressor and a decompressor based on input data input to the compressor. The compressor is partially driven according to the driving plan to generate compressed data of the input data. The decompressor is partially driven according to the driving plan to generate reconstructed data of the compressed data. The dynamic driving plan generator has already been learned based on evaluation values obtained for the driving plan. Each of the evaluation values corresponds to a respective one of evaluation indexes for the driving plan, and the evaluation values are values obtained when at least the compression of the compression and the reconstruction according to the driving plan is executed. The evaluation indexes include the execution time for one or both of the compression and the reconstruction of the data.

### BACKGROUND OF THE INVENTION

### 1. Field of the Invention

The present invention generally relates to compression control using a machine learning model (for example, a neural network).

### 2. Description of the Related Art

In order to store a large amount of data mechanically generated from IoT devices or the like at low cost, it is necessary to achieve a high compression ratio within a range of not impairing a meaning of the data. In order to achieve this, it is conceivable to perform compression using a neural network (hereinafter, referred to as NN). However, when an attempt is made to increase the compression ratio, an NN-based compressor has a complicated structure, which causes a problem of an increase in calculation time.

Therefore, it is conceivable to reduce a calculation amount using a technique disclosed in Japanese Patent No. 6054005 specification (PTL 1) or Wu, Zuxuan, Tushar Nagarajan, Abhishek Kumar, Steven Rennie, Larry S. Davis, Kristen Grauman, and Rogerio Feris. “Blockdrop: Dynamic inference paths in residual networks.” In Proceedings of the IEEE Conference on Computer Vision and Pattern Recognition, pp. 8817-8826. 2018.

### (Non-PTL 1).

An inference device disclosed in PTL 1 calculates an activity degree at each node of a first intermediate layer using an activity degree at each node of an input layer having a connection relationship with each node of the first intermediate layer, a weight of each edge, and a bias value.

An inference device disclosed in Non-PTL 1 dynamically drops a part of residual blocks (a part for performing residual inference) of a ResNet (residual network) in accordance with a determination made by a policy network based on an input image. Both the policy network and the ResNet are NNs. A policy network is learned in order to optimize a reward given in consideration of a usage rate of the residual block and prediction accuracy of the ResNet.

In the technique disclosed in PTL 1, reduction of a calculation amount is fine granularity. Therefore, it is expected that execution efficiency of a computer is reduced due to complication of a control flow, and reduction in calculation time is reduced.

On the other hand, in the technique disclosed in Non-PTL 1, the reduction of the calculation amount is sparse granularity. However, Non-PTL 1 discloses a method applied to a classification problem, and does not disclose a method applied to a regression problem such as data compression.

Therefore, even if the technique disclosed in any one of PTL 1 and Non-PTL 1 is used, it is not possible to appropriately reduce execution time for one or both of compression and reconstruction of data.

The problem described above can also be applied to a machine learning model other than the NN.

### SUMMARY OF THE INVENTION

A system generates, by a dynamic driving plan generator, a driving plan representing a dynamic partial driving target of a compressor including a plurality of partial compressors and a decompressor including a plurality of partial decompressors, based on input data input to the compressor. Each of the compressor, the decompressor, and the dynamic driving plan generator is a machine learning model. The system generates compressed data of the input data by driving a partial compressor to be driven represented by the driving plan in the compressor to which the input data and the driving plan based on the input data are input. The system generates reconstructed data of the compressed data by driving a partial decompressor to be driven represented by the driving plan in the decompressor to which the compressed data and the driving plan based on the input data corresponding to the compressed data are input. The dynamic driving plan generator has already been learned in a learning phase based on a plurality of evaluation values obtained for the driving plan. Each of the plurality of evaluation values corresponds to a respective one of a plurality of evaluation indexes for the driving plan, and the plurality of evaluation values are a plurality of values obtained when at least the compression of the compression and the reconstruction according to the driving plan is executed. The plurality of evaluation indexes include an execution time for one or both of the compression and the reconstruction of the data.

It is possible to appropriately reduce the execution time for one or both of compression and reconstruction of data.

### BRIEF DESCRIPTION OF THE DRAWINGS

FIG. 1 shows a configuration example of an entire system including an information processing system according to a first embodiment.

FIG. 2 shows a hardware configuration example of the information processing system.

FIG. 3 shows a configuration example of internal functional blocks of the information processing system.

FIG. 4 shows a configuration example of internal functional blocks of a dynamic driving plan generator.

FIG. 5 shows a configuration example of internal functional blocks of a partial compressor.

FIG. 6 shows a configuration example of internal functional blocks of a real type partial NN.

FIG. 7 shows a configuration example of internal functional blocks of an integer type partial NN.

FIG. 8 shows a configuration example of internal functional blocks of a quantizer.

FIG. 9 shows a configuration example of internal functional blocks of a dequantizer.

FIG. 10 shows a configuration example of internal functional blocks of a mixer.

FIG. 11 shows a configuration example of internal functional blocks of a reward calculator.

FIG. 12 shows a configuration example of internal functional blocks of a reward delta calculator.

FIG. 13 shows a configuration example of internal functional blocks of a quality evaluator.

FIG. 14 shows an example of a learning flow of a compressor and a decompressor.

FIG. 15 shows an example of a learning flow of the dynamic driving plan generator.

FIG. 16 shows an example of a flow of cooperative learning between the compressor and the decompressor, and the dynamic driving plan generator.

FIG. 17 shows an example of a compression flow.

FIG. 18 shows an example of a reconstruction flow.

FIG. 19 shows an example of a reward calculation flow.

FIG. 20 shows an example of a setting screen for reward calculation.

FIG. 21 shows a first method for execution time estimation.

FIG. 22 shows a second method for the execution time estimation.

FIG. 23 shows an example of a setting screen for the execution time estimation.

FIG. 24 shows a configuration example of internal functional blocks of a learning loss calculator.

FIG. 25 shows a configuration example of internal functional blocks of a rounding-off unit.

FIG. 26 shows a configuration example of internal functional blocks of a sampler.

### DESCRIPTION OF THE PREFERRED EMBODIMENTS

In the following description, an “interface device” may be one or more interface devices. The one or more interface devices may be at least one of the following devices. One or more Input/Output (I/O) interface devices. The Input/Output (I/O) interface device is an interface device for at least one of an I/O device and a remote display computer. The I/O interface device for a display computer may be a communication interface device. At least one I/O device may be a user interface device, for example, either of an input device such as a keyboard and a pointing device, and an output device such as a display device. One or more communication interface devices. The one or more communication interface devices may be one or more communication interface devices of the same type (for example, one or more network interface cards (NICs)), or may be two or more communication interface devices of different types (for example, an NIC and a host bus adapter (HBA)).

In the following description, a “memory” is one or more memory devices, and may be typically a main storage device. At least one memory device in the memory may be a volatile memory device or a non-volatile memory device.

In the following description, a “persistent storage device” is one or more persistent storage devices. Typically, the one or more persistent storage devices are a non-volatile storage device (for example, an auxiliary storage device). Specific examples of the one or more persistent storage devices include a hard disk drive (HDD) and a solid state drive (SSD).

In the following description, a “storage device” may be a physical storage device such as a persistent storage device or a logical storage device associated with a physical storage device.

Also, in the following description, a “processor” may be one or more processor devices. Typically, at least one processor device is a microprocessor device such as a central processing unit (CPU). Alternatively, the at least one processor device may be another type of processor device such as a graphics processing unit (GPU). The at least one processor device may be a single core or a multi-core. The at least one processor device may be a processor core. The at least one processor device may be a processor device in a broad sense such as a hardware circuit (for example, a field-programmable gate array (FPGA) or an application specific integrated circuit (ASIC)) that executes a part of or all processing.

In the following description, functions maybe described by expressions such as a compressor, a partial compressor, a compression functional block, a quantizer, a dequantizer, a mixer, a decompressor, a partial decompressor, a decompression functional block, a dynamic driving plan generator, a reward calculator, a reward delta calculator, a learning loss calculator, a quality evaluator, a selector, a random number generator, a quality evaluator, a comparator, and an execution time estimator. However, these functions may be implemented by executing a machine learning model or a computer program by a processor, or may be implemented by a hardware circuit (for example, an FPGA or an ASIC). When the function is implemented by the processor executing the program, since predetermined processing is executed by appropriately using a storage device and/or an interface device, the function may be at least a part of the processor. The processing described using the function as a subject may be processing performed by a processor or by a device including the processor. The program may be installed from a program source. The program source may be, for example, a recording medium (for example, a non-transitory recording medium) which can be read by a program distribution computer or a computer. A description for each function is an example. A plurality of functions may be combined into one function, and one function maybe divided into a plurality of functions.

At least apart of the compressor, the partial compressor, the compression functional block, the quantizer, the dequantizer, the mixer, the decompressor, the partial decompressor, the decompression functional block, the dynamic driving plan generator, the reward calculator, the reward delta calculator, the learning loss calculator, the quality evaluator, the selector, the sampler, the quality evaluator, the comparator, and the execution time estimator, for example, at least a part of the reward calculator, the reward delta calculator, and the learning loss calculator may be implemented by the hardware circuit.

In the following description, a common part in reference numerals may be used when elements of the same type are described without distinction, and a reference numeral may be used when the elements of the same type are distinguished.

### First Embodiment

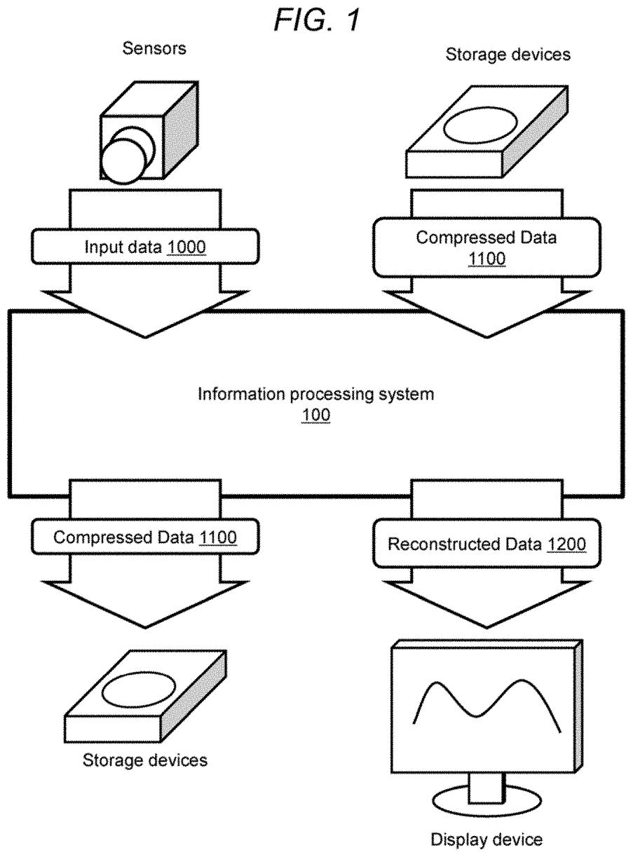

FIG. 1 shows a configuration example of an entire system including an information processing system according to a first embodiment.

An information processing system 100 controls data input and output.

For example, the information processing system 100 receives input data 1000, compresses the input data 1000, and outputs compressed data 1100. An input source of the input data 1000 may be one or more sensors (and/or one or more other types of devices). An output destination of the compressed data 1100 may be one or more storage devices (and/or one or more other types of devices).

For example, the information processing system 100 receives the compressed data 1100, reconstructs the compressed data 1100, and outputs reconstructed data 1200. An input source of the compressed data 1100 may be one or more storage devices (and/or one or more other types of devices). An output destination of the reconstructed data 1200 may be a display device (and/or one or more other types of devices).

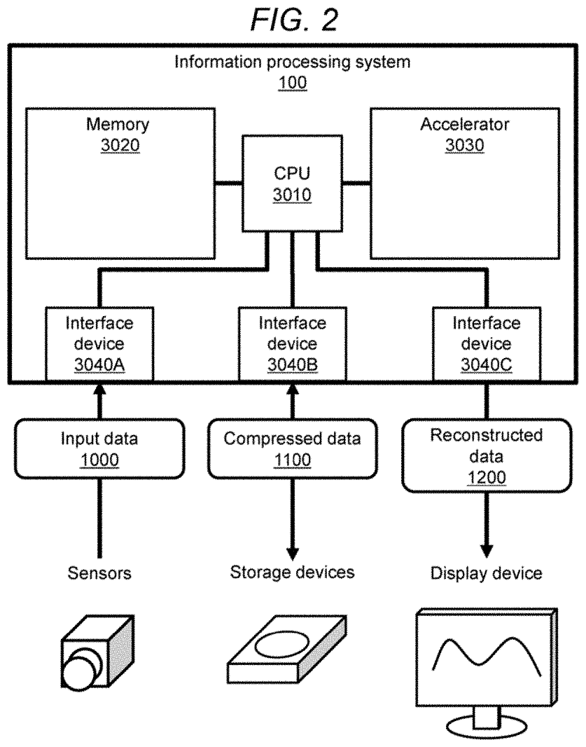

FIG. 2 shows a hardware configuration example of the information processing system 100.

The information processing system 100 is a system including one or more physical computers. The information processing system 100 includes one or more interface devices 3040 as an example of an interface device, a memory 3020 as an example of a storage device, and a CPU 3010 and an accelerator 3030 as an example of a processor.

The interface devices 3040 include, for example, an interface device 3040A that allows the input data 1000 to be input, an interface device 3040B that allows the compressed data 1100 to be input and output, and an interface device 3040C that allows the reconstructed data 1200 to be output.

The interface devices 3040A to 3040C, the memory 3020, and the accelerator 3030 are connected to the CPU 3010. The accelerator 3030 is a hardware circuit that executes predetermined processing at a high speed, and may be, for example, a parallel calculation device such as a graphics processing unit (GPU). The CPU 3010 executes processing other than the processing executed by the accelerator 3030 using the memory 3020 as appropriate. An NN and the program that are executed by the CPU 3010 and the accelerator 3030, and data (for example, padding data 1400, an offset, a scale, a criteria 1640, a priority 1650, a penalty 1630, various weights, and the like described later) input and output in the execution of the NN and the program are stored in, for example, the memory 3020.

The “information processing system” may be another type of system instead of the system including one or more physical computers, for example, a system (for example, a cloud computing system) implemented on a physical calculation resource group (for example, a cloud infrastructure).

In the present embodiment, the input data 1000 is image data that is an example of multidimensional data. The image data is data representing one image, but may be data representing a plurality of images. The image data maybe still image data or moving image data. The input data 1000 may be other types of multidimensional data such as audio data instead of image data. The input data 1000 maybe one-dimensional data instead of or in addition to the multidimensional data.

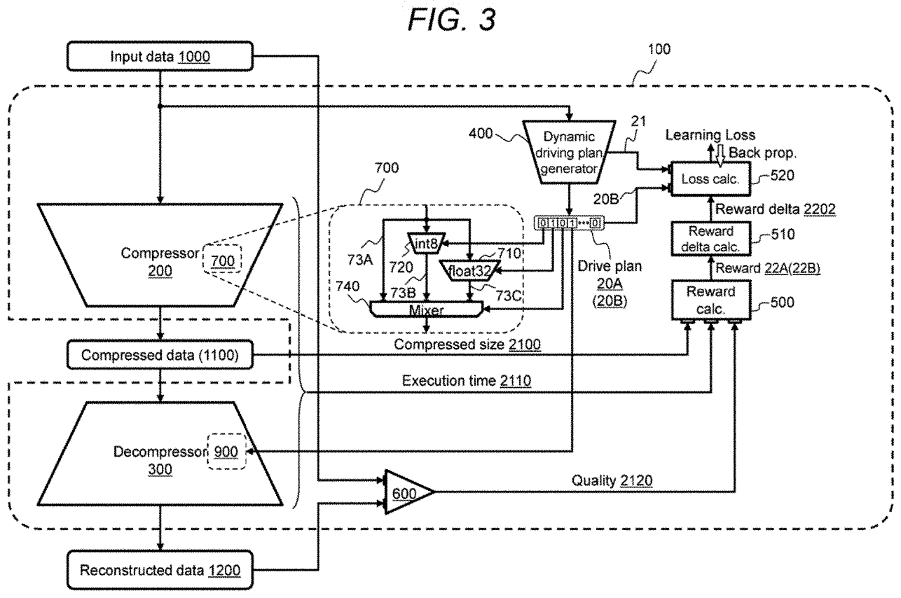

FIG. 3 shows a configuration example of internal functional blocks of the information processing system 100.

The information processing system 100 includes a compressor 200, a decompressor 300, a quality evaluator 600, a dynamic driving plan generator 400, a reward calculator 500, a reward delta calculator 510, and a learning loss calculator 520. Each of the compressor 200, the decompressor 300, and the dynamic driving plan generator 400 is a neural network. However, instead of the neural network, other types of machine learning models, for example, gaussian mixture models (GMM), hidden markov model (HMM), stochastic context-free grammar (SCFG), generative adversarial nets (GAN), variational auto encoder (VAE), or genetic programming may be used. In order to reduce the information amount of the model, model compression such as a Mimic Model may be applied.

The compressor 200, the decompressor 300, the dynamic driving plan generator 400, the quality evaluator 600, the reward calculator 500, the reward delta calculator 510, and the learning loss calculator 520 may be operated (driven) by being executed by the processor. For example, the compressor 200, the decompressor 300, and the dynamic driving plan generator 400 may be executed by the accelerator 3030.

The compressor 200 receives the input data 1000, compresses the input data 1000, and outputs the compressed data 1100. The compressor 200 includes a plurality of partial compressors 700. The compression performed by the compressor 200 may be reversible compression or irreversible compression. In the present embodiment, reversible compression may be included in a part, but irreversible compression is used as a whole.

The partial compressor 700 includes a plurality of data paths 73 and a mixer 740 that outputs data based on data flowing through the plurality of data paths 73. The data path 73 includes a skip path 73A and compression paths 73B and 73C. The skip path 73A is a data path that does not pass through any of the compression functional blocks. Each of the compression paths 73B and 73C is a data path that passes through the compression functional blocks. The compression functional block is a functional block that performs compression processing, and is, for example, a partial NN. The partial NN includes a real type partial NN 710 and an integer type partial NN 720. The real type partial NN 710 is an example of the compression functional block that performs the reversible compression. The integer type partial NN 720 is an example of a compression functional block that performs the irreversible compression. That is, the plurality of compression paths are a plurality of data paths each passing through a respective one of a plurality of compression functional blocks. The plurality of compression functional blocks perform compression having different compression qualities.

The decompressor 300 receives the compressed data 1100, reconstructs the compressed data 1100, and outputs the reconstructed data 1200. The decompressor 300 is different from the compressor 200 in that reconstruction is performed instead of compression. However, the configuration of the decompressor 300 is the same as the configuration of the compressor 200. That is, the decompressor 300 includes a plurality of partial decompressors 900. Due to a difference between the compression and the reconstruction, a configuration of the partial decompressor 900 may be symmetrical to the configuration of the partial compressor 700.

The quality evaluator 600 receives the input data 1000 and the reconstructed data 1200 and outputs a quality 2120. The reconstructed data 1200 to be input is data obtained by reconstructing the compressed data 1100 of the input data 1000 to be input together. The quality 2120 is data representing the compression quality based on a delta between the input data 1000 and the reconstructed data 1200, in other words, an evaluation value serving as the compression quality. An output destination of the quality 2120 is the reward calculator 500.

The dynamic driving plan generator 400 generates a driving plan 20 based on the input data 1000. The driving plan 20 is data representing which one or more partial compressors 700 in the compressor 200 to which the input data 1000 is input are to be dynamically driven. Specifically, the driving plan 20 represents a driving content including which compression functional block of the partial compressor 700 to be driven is to be driven for the partial compressor 700. Details of the driving plan 20 will be described later.

The reward calculator 500 inputs a plurality of evaluation values for each of a first driving plan 20A and a second driving plan 20B for the same input data 1000, and outputs a first reward 22A and a second reward 22B respectively corresponding to the first driving plan 20A and the second driving plan 20B.

The first driving plan 20A is a driving plan output based on a driving probability 21 described later in an inference phase. The first driving plan 20A is output as a reference system based on the driving probability 21 in a learning phase of the dynamic driving plan generator 400. On the other hand, the second driving plan 20B is a driving plan that is output as a result of sampling based on the driving probability 21 for learning (optimization of the first driving plan 20A (to be precise, the driving probability 21 that is a basis of the first driving plan 20A)) of the dynamic driving plan generator 400 in the learning phase of the dynamic driving plan generator 400.

For each of the first driving plan 20A and the second driving plan 20B, the plurality of evaluation values are a plurality of values each corresponding to a respective one of a plurality of evaluation indexes for the driving plan 20. In the present embodiment, examples of the plurality of evaluation indexes include a compressed size, an execution time, and a compression quality. An illustrated compressed size 2100 is data representing a size of the compressed data 1100, in other words, an evaluation value serving as the compressed size. The compressed size may be an example of a compression effect. As the compression effect, for example, a delta between the size of the input data 1000 and the size of the compressed data 1100 may be adopted, or a compression ratio based on the sizes may be adopted. An execution time 2110 is data representing the execution time for one or both of compression and reconstruction of data, in other words, an evaluation value serving as the execution time. In the present embodiment, the execution time 2110 is an actual measurement value.

The first reward 22A is a value calculated by the reward calculator 500 based on the compressed size 2100, the execution time 2110, and the quality 2120. The compressed size 2100, the execution time 2110, and the quality 2120 are obtained for the first driving plan 20A. The second reward 22B is a value calculated by the reward calculator 500 based on the compressed size 2100, the execution time 2110, and the quality 2120. The compressed size 2100, the execution time 2110, and the quality 2120 are obtained for the second driving plan 20B.

The reward delta calculator 510 receives the first reward 22A and the second reward 22B and outputs a reward delta 2202. The reward delta 2202 is a value representing a delta obtained by subtracting the first reward 22A from the second reward 22B.

The learning loss calculator 520 calculates a loss value necessary for learning of the dynamic driving plan generator 400 based on the driving probability 21 obtained from the dynamic driving plan generator 400, the second driving plan 20B obtained by sampling from the driving probability 21, and the reward delta 2202 described above. A learner, which is an example of a function implemented by the accelerator 3030 (or the CPU 3010), performs learning processing of the dynamic driving plan generator 400. In the learning processing, the learner calculates a gradient by performing an error back propagation calculation based on the loss value, and updates an internal parameter of the dynamic driving plan generator 400 based on the gradient.

The driving plan 20 is, for example, a set (for example, a bitmap) of a plurality of values each corresponding to a respective one of a plurality of elements. Each of the “plurality of elements” of the driving plan 20 (and the driving probability 21) is a definition element of the driving content (for example, whether to be driven). One partial compressor 700 (and one partial decompressor 900) has one or more elements (for example, whether the partial compressor 700 is to be driven and which data path 73 in the partial compressor 700 is to be used).

When it is ideal that the execution time is zero based on a viewpoint of reducing the execution time, it is ideal that all the elements are not to be driven. Therefore, it is necessary to learn the dynamic driving plan generator 400 based on whether it is appropriate for the elements to be driven based on the driving plan 20. As will be described later, in the present embodiment, in the calculation of the reward 22, the driving plan 20 is multiplied, and a result becomes a basis of the reward 22. Therefore, in the present embodiment, in the driving plan 20, a value corresponding to the element to be driven is set to a value (for example, “1”) larger than 0.

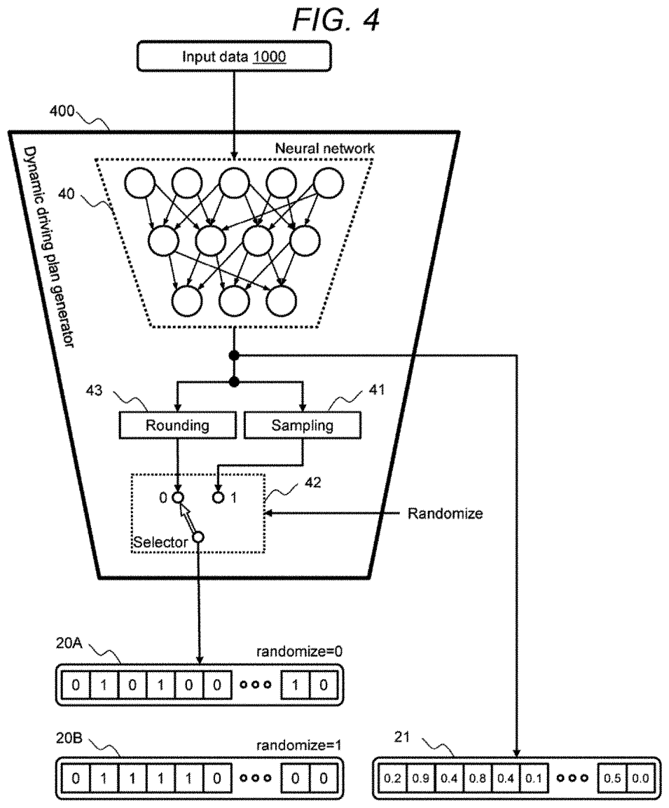

FIG. 4 shows a configuration example of internal functional blocks of the dynamic driving plan generator.

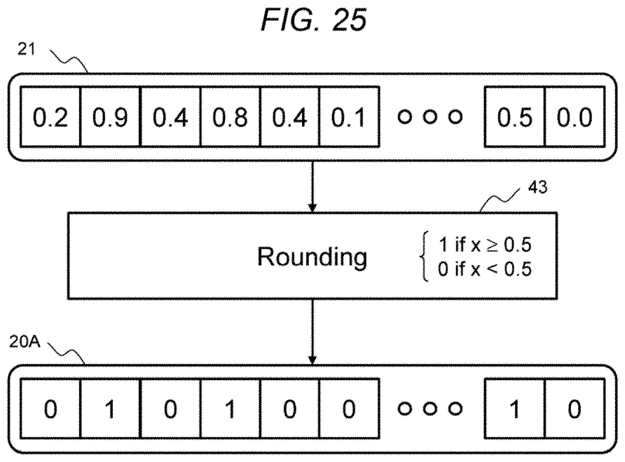

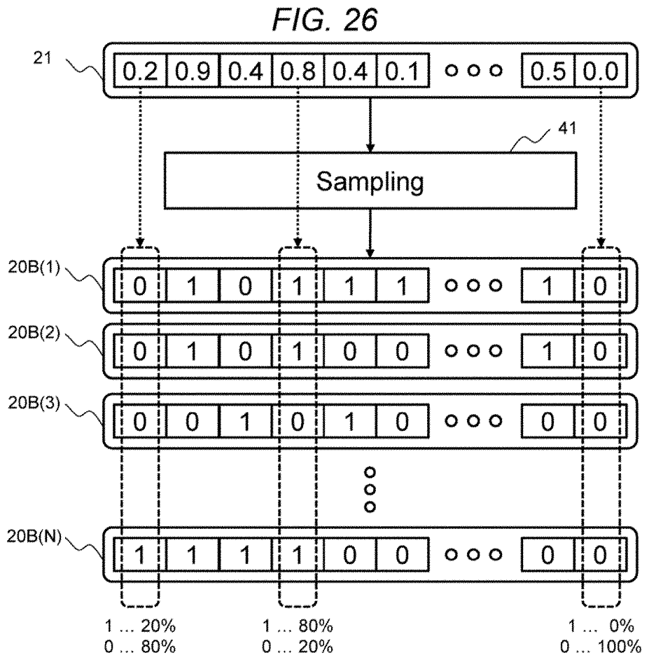

The dynamic driving plan generator 400 includes, in addition to the NN 40, a sampler 41, a selector 42, and a rounding-off unit 43. When a value “0” is designated in the selector 42, the first driving plan 20A is the output of the dynamic driving plan generator 400. When a value “1” is designated in the selector 42, the second driving plan 20B is the output of the dynamic driving plan generator 400. As shown in FIG. 25, the first driving plan 20A is a driving plan in which the driving probability 21 is rounded down to 0 or rounded up to 1for each of the plurality of elements by the rounding-off unit 43. The driving probability 21 has, for each of the plurality of elements, a value between 0 and 1 (that is, 0 or more and 1 or less) output from the NN 40 based on the input data 1000. As shown in FIG. 26, the second driving plan 20B is a driving plan in which, for each of the plurality of elements, a probability (value of 0 or more and 1 or less) indicated by the driving probability 21 is converted to 0 or 1 at the probability designated in the driving probability 21 using the probability (value) and a random number. The driving plan 21 includes, for each of the plurality of elements (for example, a plurality of partial compressors 700) related to the compressor 200, a probability (for example, a probability that the element is driven) of the element. For each element, the probability is a value of 0 or more and 1 or less as described above. In the learning phase, the first driving plan 20A serving as a reference system and one or a plurality of second driving plans 20B are generated based on the driving probability 21 obtained by the dynamic driving plan generator 400 to which the input data 1000 is input. As a result, for the input data 1000, the second reward 22B is generated for each second driving plan 20B, and for each second reward 22B, the reward delta 2202 which is a delta from the first reward 22A based on the first driving plan 20A is generated.

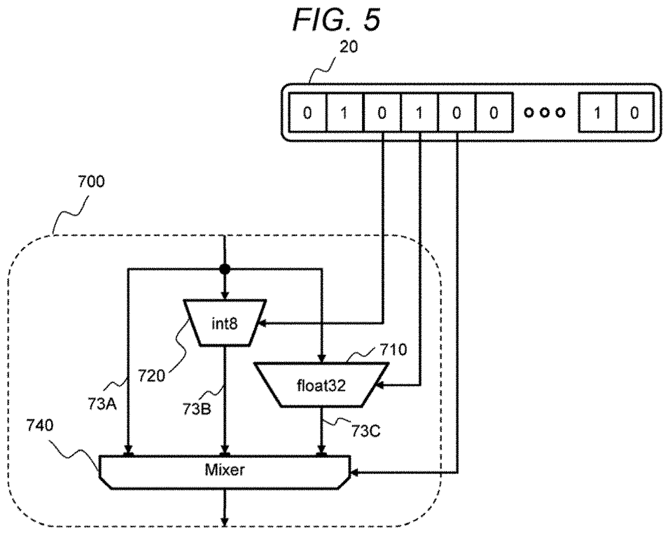

FIG. 5 shows a configuration example of internal functional blocks of the partial compressor 700.

As described above, the partial compressor 700 includes the plurality of data paths 73 (the skip path 73A and the compression paths 73B and 73C) and the mixer 740. The driving plan 20 represents the driving content of the partial compressor 700. The driving content represents, for example, one or more data paths 73 to be enabled (or disabled) and a calculation method executed by the mixer 740 using a plurality of values obtained via the plurality of data paths 73.

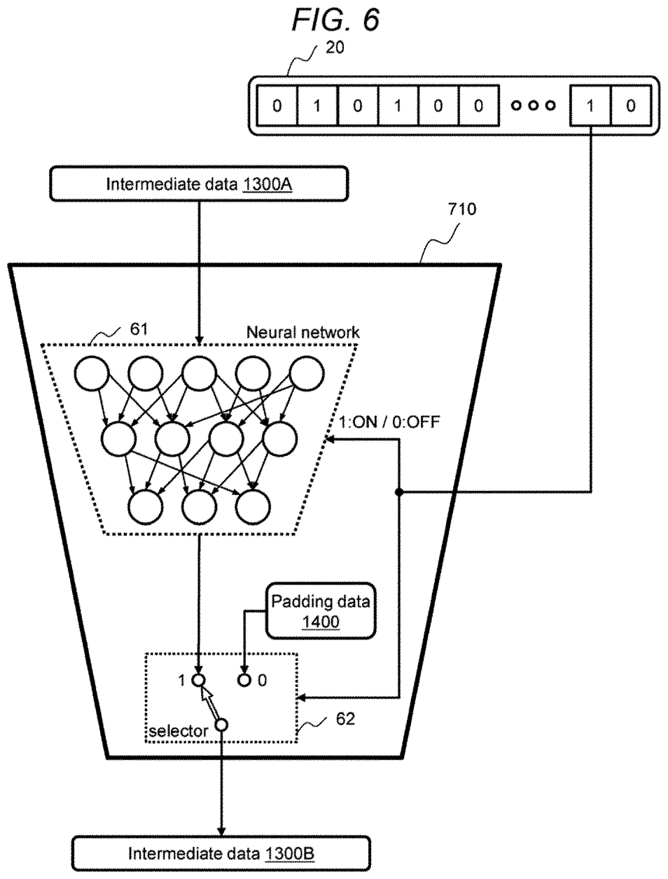

FIG. 6 shows a configuration example of internal functional blocks of the real type partial NN 710.

The real type partial NN 710 includes a selector 62 in addition to an NN 61. Intermediate data 1300A is data input to the partial compressor 700 including the real type partial NN 710.

When the real type partial NN 710 is to be driven in the driving plan 20 (when the value corresponding to the real type partial NN 710 is “1” in the driving plan 20), “1” is designated to each of the NN 61 and the selector 62. As a result, the intermediate data 1300A is input to the NN 61, and data is output from the NN 61 via the selector 62. The data output from the selector 62 is intermediate data 1300B output from the real type partial NN 710.

When the real type partial NN 710 is not to be driven in the driving plan 20 (when the value corresponding to the real type partial NN 710 is “0” in the driving plan 20), “0” is designated to each of the NN 61 and the selector 62. As a result, since the NN 61 is not driven, the padding data 1400 is output via the selector 62. The padding data 1400 is the intermediate data 1300B.

The padding data 1400 is, for example, data prepared in advance, and may be, for example, data in which all bits are “0” (this also applies to the following description).

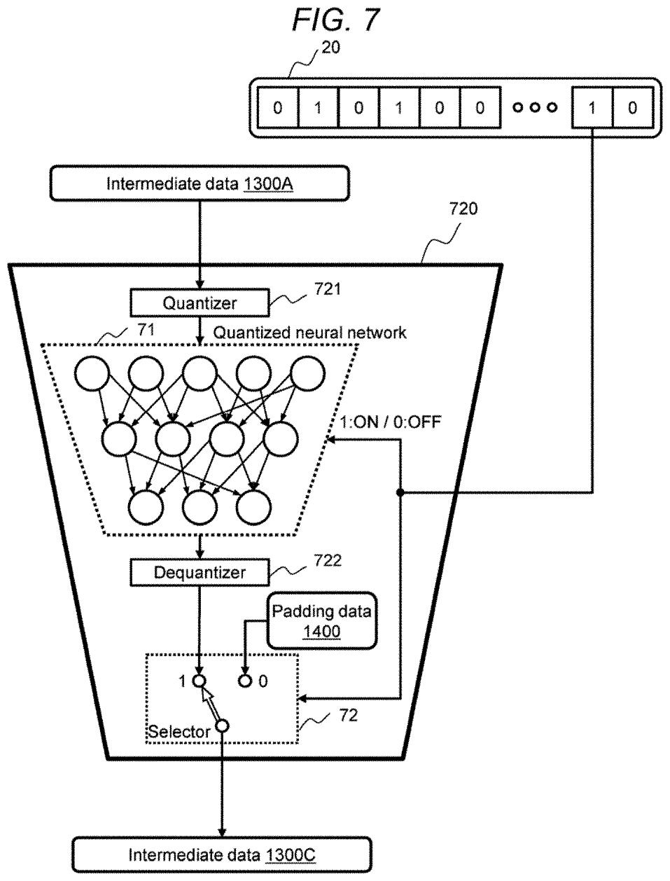

FIG. 7 shows a configuration example of internal functional blocks of the integer type partial NN 720.

The integer type partial NN 720 includes a quantizer 721, a dequantizer 722, and a selector 72 in addition to an NN 71.

When the integer type partial NN 720 is to be driven in the driving plan 20 (when a value corresponding to the integer type partial NN 720 is “1” in the driving plan 20), “1” is designated to each of the NN 71 and the selector 72. As a result, the intermediate data 1300A is quantized (integerized) by the quantizer 721 and input to the NN 71. The data that is output from the NN 71 and is dequantized by the dequantizer 722 is output via the selector 72. The data output from the selector 72 is intermediate data 1300C output from the integer type partial NN 720.

When the integer type partial NN 720 is not to be driven in the driving plan 20 (when the value corresponding to the integer type partial NN 720 is “0” in the driving plan 20), “0” is designated to each of the NN 71 and the selector 72. As a result, since the NN 71 is not driven, the padding data 1400 is output via selector 72. The padding data 1400 is the intermediate data 1300C.

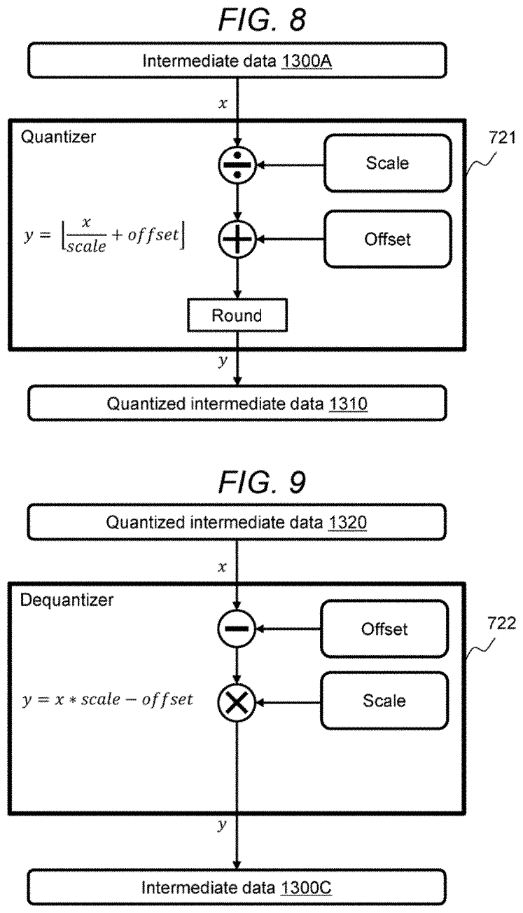

FIG. 8 shows a configuration example of internal functional blocks of the quantizer 721.

The quantizer 721 divides a value x (typically, a value including a decimal point) represented by the intermediate data 1300A by a predetermined scale so as to obtain a value that falls within an integer range. The quantizer 721 adds a predetermined offset to a value obtained by the division so as not to cause overflow, and rounds down after the decimal point to output intermediate data 1310 representing an integer y. The intermediate data 1310 is input to the NN 71.

FIG. 9 shows a configuration example of internal functional blocks of the dequantizer 722.

The dequantizer 722 executes calculation opposite to that executed by the quantizer 721. That is, the dequantizer 722 subtracts the above-described predetermined offset from the value x represented by intermediate data 1320 output from the NN 71, and multiplies the value obtained by the subtraction by the above-described predetermined scale. Data representing the value y obtained by the multiplication is output as the intermediate data 1300C.

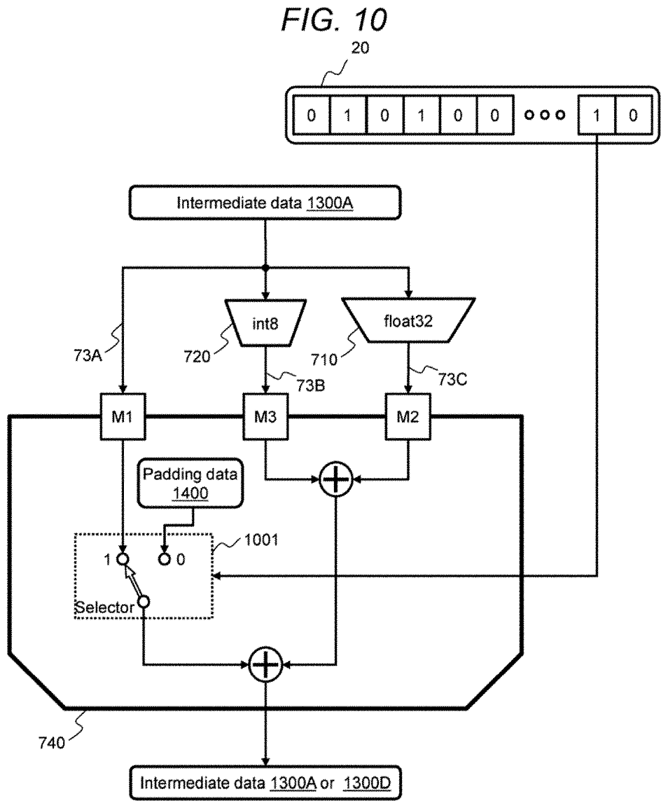

FIG. 10 shows a configuration example of internal functional blocks of the mixer 740.

A value M1, a value M3, and a value M2 are input to the mixer 740 via the data paths 73A to 73C. The value M1 is data input via the skip path 73A, that is, the intermediate data 1300A. The value M3 is data input via the compression path 73B, that is, the intermediate data 1300C (see FIG. 7). The value M2 is data input via the compression path 73C, that is, the intermediate data 1300B (see FIG. 6).

For the intermediate data 1300A, it is possible that one of the real type partial NN 710 and the integer type partial NN 720 is to be driven or neither the real type partial NN 710 nor the integer type partial NN 720 is to be driven. For the intermediate data 1300A, it is not possible that both the real type partial NN 710 and the integer type partial NN720 are to be driven. Therefore, one or both of the value M3 and the value M2 are the padding data 1400. The value M3 and the value M2 are added.

The mixer 740 includes a selector 1001. In the driving plan 20, when the value corresponding to the mixer 740 is “1”, the value M1 is output via the selector 1001. In the driving plan 20, when the value corresponding to the mixer 740 is “0”, the padding data 1400 is output via the selector 1001.

When the partial compressor 700 including the mixer 740 shown in FIG. 10 is not to be driven, the output (that is, the output of the partial compressor 700) of the mixer 740 is the same intermediate data 1300A as the input of the partial compressor 700. Specifically, it is as follows. That is, neither the partial NN 710 nor the partial NN 720 is to be driven, and the value “1” is designated to the selector 1001. Therefore, both the value M3 and the value M2 are the padding data. Even if the values are added, the padding data is output. The value M1 (the intermediate data 1300A) is output from the selector 1001. Therefore, the intermediate data 1300A is added to the padding data. As a result, the output of the mixer 740 is the intermediate data 1300A. As described above, since the partial compressor 700 is not driven, the intermediate data 1300A input to the partial compressor 700 is directly output from the partial compressor 700 via the skip path 73A (and the selector 1001).

When the partial compressor 700 including the mixer 740 shown in FIG. 10 is to be driven, since one of the partial NNs 710 and 720 is to be driven, the output (that is, the output of the partial compressor 700) of the mixer 740 is intermediate data 1300D. Specifically, the output of the mixer 740 is one of the following.

The value “0” is designated to the selector 1001. The value M3 or the value M2 is the padding data. When the values are added, the value M3 or the value M2 is output. The padding data 1400 is output from the selector 1001. Therefore, the value M3 or the value M2 is added to the padding data 1400. As a result, the intermediate data 1300D serving as the output of the mixer 740 is the value M3 or the value M2. The value “1” is designated to the selector 1001. The value M3 or the value M2 is the padding data. When the values are added, the value M3 or the value M2 is output. The value M1 (the intermediate data 1300A) is output from the selector 1001. Therefore, the value M3 or the value M2 is added to the value M1. As a result, the intermediate data 1300D serving as the output of the mixer 740 is a sum of the value M1 and the value M3 or the value M2.

The calculation executed by the mixer 740 maybe, instead of or in addition to the addition, another type of calculation, for example, at least one of subtraction, multiplication, and division. The mixer 740 may calculate a transcendental function. A calculation method executed by the mixer 740 may be expressed by a predetermined number of bits in the driving plan 20.

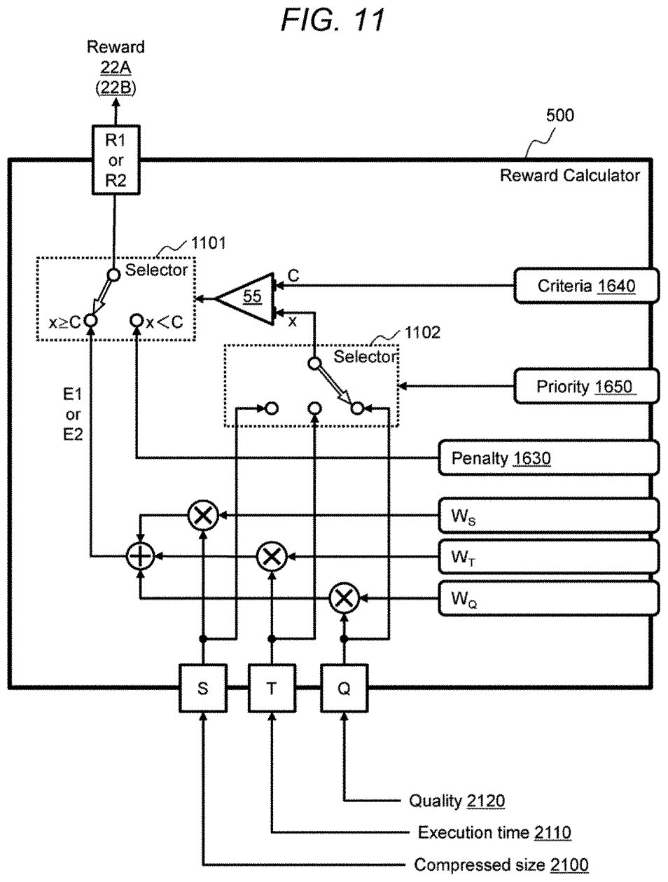

FIG. 11 shows a configuration example of internal functional blocks of the reward calculator 500.

The reward calculator 500 includes selectors 1101 and 1102 and a comparator 55.

For the same input data 1000, a value Q, a value T, and a value S corresponding to the first driving plan 20A and the second driving plan 20B are input to the reward calculator 500. The value Q is the quality 2120. The value T is the execution time 2110. The value Q is the compressed size 2100.

The reward calculator 500 calculates a value E1 and a value E2 corresponding to the first driving plan 20A and the second driving plan 20B. The value E1 is a value based on the value Q, the value T, and the value S that correspond to the first driving plan 20A. The value E2 is a value based on the value Q, the value T, and the value S that correspond to the second driving plan 20B.

For the same input data 1000, a value R1 and a value R2 are output from the reward calculator 500. The value R1 is data representing the reward corresponding to the first driving plan 20A, that is, the first reward 22A. The value R2 is data representing the reward corresponding to the second driving plan 20B, that is, the second reward 22B.

Processing for calculating the value R1 will be described by taking a case as an example. In the case, the value Q, the value T, and the value S that correspond to the first driving plan 20A are input to the reward calculator 500.

The reward calculator 500 calculates the value E1 based on the value Q, the value T, and the value S. For each of the value Q, the value T, and the value S, a weight of an evaluation index corresponding to the value is prepared, and weights of evaluation indexes corresponding to the value Q, the value T, and the value S are reflected in the calculation of the value E1. That is, a weight W_{Q} of the value Q is reflected in the value Q. A weight W_{T} of the value T is reflected in the value T. A weight W_{S} of the value S is reflected in the value S. More specifically, the value E1 is a sum of a product of the value Q and the weight W_{Q}, a product of the value T and the weight W_{T}, and a product of the value S and the weight W_{S}.

The selector 1102 selects one of the value Q, the value T, and the value S based on the priority 1650, and outputs the selected value x. The priority 1650 is data indicating which evaluation index among a plurality of evaluation indexes (in the present embodiment, the compression quality, the execution time, and the compressed size) has the highest priority. The selector 1102 selects a value corresponding to the evaluation index that is represented by the priority 1650 and has the highest priority.

The comparator 55 compares the value x with a value C, and outputs a value representing a relationship between the value x and the value C (x≥C or x<C). The value C is a value acquired from the criteria 1640. The criteria 1640 is data representing a criteria value (a threshold to be compared with a value output from the selector 1102) of the evaluation index that is represented by the priority 1650 and has the highest priority. In the present embodiment, in order to simplify the description, regardless of the evaluation index, “x≥C” means that an evaluation value satisfies the criteria value, and x<C means that the evaluation value does not satisfy the criteria value. Therefore, for example, when the value x is the compressed size 2100, “x≥C” means that the compression is performed to a sufficiently small size. For example, when the value x is the execution time 2110, “x≥C” means that the execution time is sufficiently reduced. For example, when the value x is the quality 2120, “x≥C” means that the compression quality is sufficiently high.

The selector 1101 performs the selection according to the value output from the comparator 55. When the value output from the comparator 55 means “x≥C”, the selector 1101 outputs the value E1. On the other hand, when the value output from the comparator 55 means “x<C”, the selector 1101 outputs the penalty 1630. The penalty 1630 may be data having the same structure as a value D1 (the driving plan 20A), and may be, for example, data of a penalty value in which values of all bits are “−1”.

Finally, the reward calculator 500 outputs the value R1 selected as the output of the selector 1101.

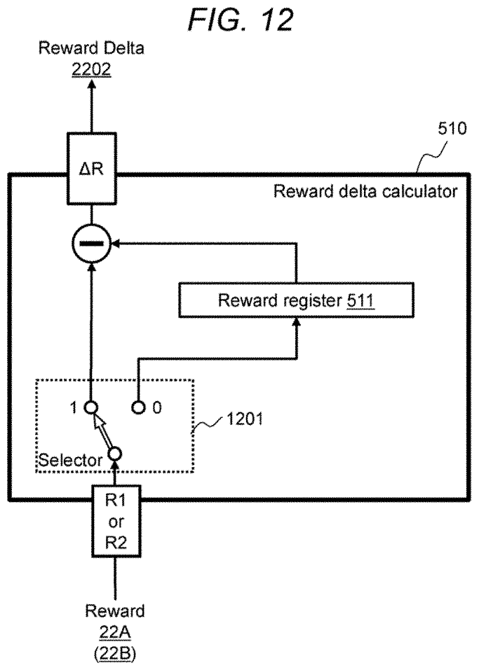

FIG. 12 shows a configuration example of internal functional blocks of the reward delta calculator 510.

The reward delta calculator 510 includes a selector 1201 and a reward register 511 (an example of a storage region).

For the same input data 1000, the value R1 and the value R2 respectively corresponding to the first driving plan 20A and the second driving plan 20B are input to the reward delta calculator 510. The selector 1201 selects to output the value R1 of the value R1 and the value R2 to the reward register 511. The value R1 corresponds to the first driving plan 20A. As a result, the value R1 is temporarily stored in the reward register 511.

The reward delta calculator 510 calculates a reward delta (value ΔR) by subtracting the value R1 stored in the reward register 511 from the value R2 input later. The reward delta calculator 510 outputs the value ΔR. An output value ΔR 2202 is input to the learning loss calculator 520.

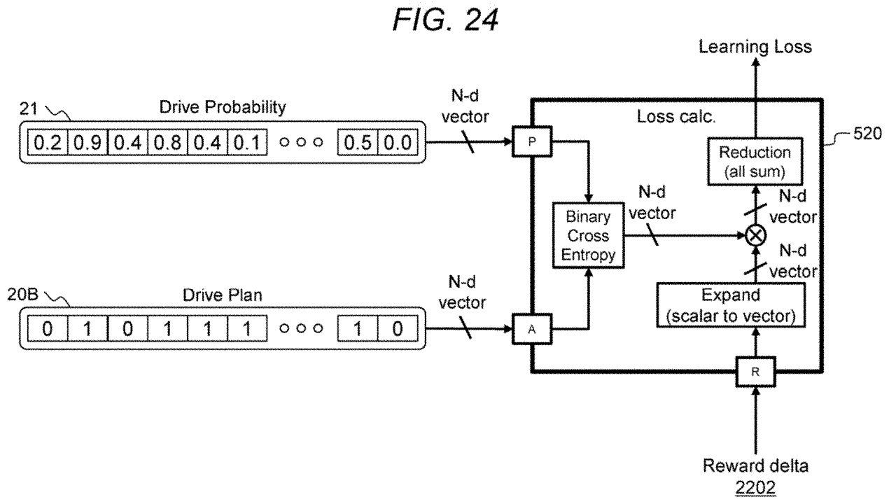

FIG. 24 shows a configuration example of internal functional blocks of the learning loss calculator 520.

The learning loss calculator 520 receives the driving probability 21 and the second driving plan 20B, and calculates, for each of the plurality of elements, a binary cross entropy value between the value in the driving probability 21 and the second driving plan 20B. The learning loss calculator 520 multiplies each of the plurality of binary cross entropy values corresponding to a respective one of the plurality of elements by the reward delta 2202. Since the reward delta 2202 is a scalar value, the reward delta 2202 (scalar value) is copied (that is, extended) by the number of the elements by the learning loss calculator 520 in order to multiply the binary cross entropy value, which is a vector value, by the reward delta 2202 for each element. As a result, the reward delta 2202 is present for each of the plurality of elements. The learning loss calculator 520 calculates a multiplication value of the binary cross entropy value and the reward delta 22 for each element, and obtains a loss value in a scalar format by adding up all of a plurality of multiplication values each corresponding to a respective one of the plurality of elements.

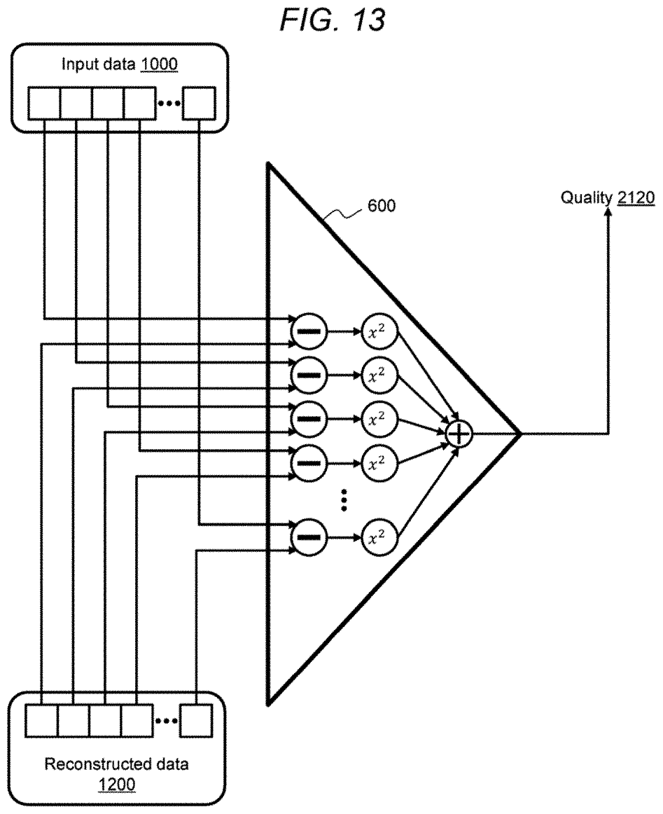

FIG. 13 shows a configuration example of internal functional blocks of the quality evaluator 600.

The quality evaluator 600 receives the input data 1000 and the reconstructed data 1200, and outputs the quality 2120 representing the compression quality according to the delta between the input data 1000 and the reconstructed data 1200. Any method may be adopted as the calculation method of the quality 2120. According to the example shown in FIG. 13, the quality evaluator 600 calculates, as the quality 2120, a sum of squares of delta between N data blocks (N is an integer of 2 or more) constituting the input data 1000 and N data blocks (the same number of data blocks) constituting the reconstructed data 1200.

Hereinafter, several pieces of processing executed in the present embodiment will be roughly divided into a learning phase and an inference phase.

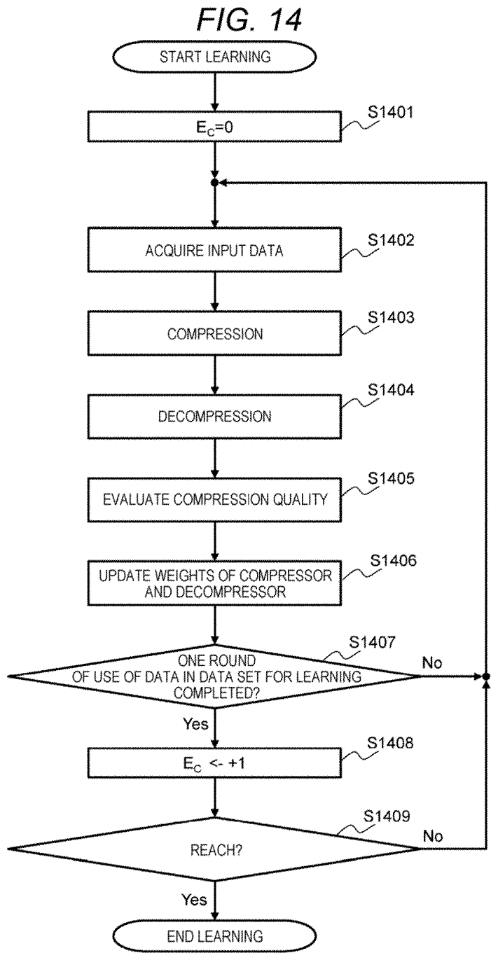

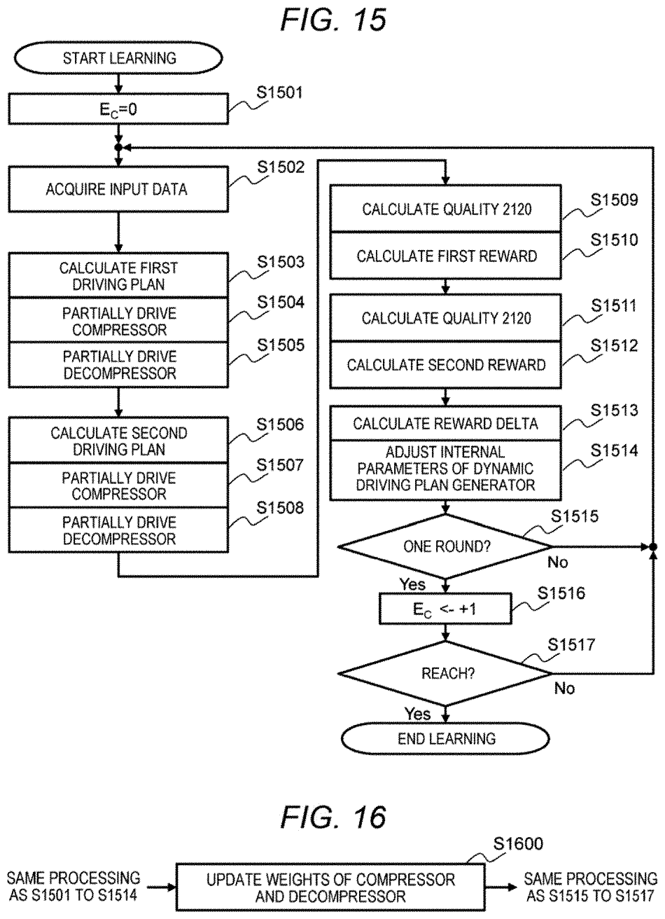

In the learning phase, learning of the compressor 200 and the decompressor 300 is executed (see FIG. 14). Then, learning of the dynamic driving plan generator 400 is executed (see FIG. 15). Finally, cooperative learning between the compressor 200 and the decompressor 300 and the dynamic driving plan generator 400 is executed (see FIG. 16).

FIG. 14 shows an example of a learning flow of the compressor 200 and the decompressor 300.

In S1401, a learner, which is an example of a function implemented by the accelerator 3030 (or the CPU 3010), sets E_{c} (epoch number counter) to “0”.

In S1402, the learner reads mini-batch data from a data set. The “data set” may be a teacher data set, and may be, for example, a data set in which a label is associated with each image. The mini-batch data may be a part or all of the data set, and is an example of the input data 1000 in the learning phase.

In S1403, the learner executes the compression by executing forward propagation processing in the compressor 200. That is, the learner obtains the output of the compressed data 1100 from the compressor 200 by inputting the input data 1000 to the compressor 200.

In S1404, the learner executes reconstruction by executing the forward propagation processing in the decompressor 300. That is, the learner inputs the compressed data 1100 to the decompressor 300 to obtain the output of the reconstructed data 1200 from the decompressor 300.

In S1405, the learner evaluates the compression quality using the quality evaluator 600. That is, the learner inputs the input data 1000 and the reconstructed data 1200 to the quality evaluator 600 to obtain the output of the quality 2120 from the quality evaluator 600.

In S1406, the learner updates the weights (internal parameters) of the compressor 200 and the decompressor 300 using an error back propagation method based on the quality 2120.

In S1407, the learner determines whether one round of use of the data in the data set for learning is completed. When a result of the determination is false, the processing returns to S1402.

When the determination result in S1407 is true, the learner increments E_{c} by 1 in S1408.

In step S1409, the learner determines whether the updated E_{c} reaches a predetermined value. When a result of the determination is false, the processing returns to S1402. When the result of the determination is true, the learning of the compressor 200 and the decompressor 300 ends.

FIG. 15 shows an example of a learning flow of the dynamic driving plan generator 400.

In S1501, the learner sets the E_{c} (epoch number counter) to “0”.

In S1502, the learner reads mini-batch data from a data set. As described above, the mini-batch data is an example of the input data 1000 in the learning phase.

In S1503, the learner inputs the input data 1000 (mini-batch data) to the dynamic driving plan generator 400, so that the dynamic driving plan generator 400 executes forward propagation calculation, and as a result, outputs the first driving plan 20A.

In S1504, the learner inputs the same input data 1000 and the first driving plan 20A output in S1503 to the compressor 200, so that the compressor 200 executes partial driving (executes the forward propagation calculation) according to the first driving plan 20A, and as a result, outputs the compressed data 1100.

In S1505, the learner inputs the compressed data 1100 output in S1504 and the first driving plan 20A output in S1503 to the decompressor 300, and thus the decompressor 300 executes the partial driving (executes the forward propagation calculation) according to the first driving plan 20A, and as a result, outputs the reconstructed data 1200.

A first data group including the first driving plan 20A, the input data 1000, and the compressed data 1100 and the reconstructed data 1200 that correspond to the first driving plan 20A is stored in the memory 3020 by, for example, the learner. The learner measures the size of the compressed data 1100 and the execution time taken for compression and reconstruction according to the first driving plan 20A, and includes the compressed size 2100 and the execution time 2110 in the first data group.

In S1506, for example, the learner inputs the same input data 1000 as the value “0” for the selector 42 to the dynamic driving plan generator 400 and sets the value “1” for the selector 42, thereby causing the dynamic driving plan generator 400 to generate the second driving plan 20B.

In S1507, the learner inputs the same input data 1000 and the second driving plan 20B output in S1506 to the compressor 200, so that the compressor 200 executes the partial driving according to the second driving plan 20B, and as a result, outputs the compressed data 1100.

In S1508, the learner inputs the compressed data 1100 output in S1507 and the second driving plan 20B output in S1506 to the decompressor 300, so that the decompressor 300 is partially driven according to the second driving plan 20B. As a result, the reconstructed data 1200 is output.

A second data group including the second driving plan 20B, the input data 1000, and the compressed data 1100 and the reconstructed data 1200 that correspond to the second driving plan 20B is stored in the memory 3020 by, for example, the learner. The learner measures the size of the compressed data 1100 and the execution time taken for compression and reconstruction according to the second driving plan 20B, and includes the compressed size 2100 and the execution time 2110 in the second data group.

In S1509, the learner inputs the input data 1000 and the reconstructed data 1200 in the first data group to the quality evaluator 600. As a result, the quality evaluator 600 calculates the quality 2120 according to the delta between the input data 1000 and the reconstructed data 1200, and outputs the quality 2120.

In S1510, the learner inputs the quality 2120 output in S1509, and the compressed size 2100 and the execution time 2110 in the first data group to the reward calculator 500, so that the reward calculator 500 calculates the first reward 22A and outputs the first reward 22A.

In S1511, the learner inputs the input data 1000 and the reconstructed data 1200 in the second data group to the quality evaluator 600. As a result, the quality evaluator 600 calculates the quality 2120 according to the delta between the input data 1000 and the reconstructed data 1200, and outputs the quality 2120.

In S1512, the learner inputs the quality 2120 output in S1511, and the compressed size 2100 and the execution time 2110 in the second data group to the reward calculator 500, so that the reward calculator 500 calculates the second reward 22B and outputs the second reward 22B.

In S1513, the reward delta calculator 510 calculates the reward delta 2202 by subtracting the first reward 22A from the second reward 22B. The learning loss calculator 520 calculates a loss value based on the reward delta 2202, the driving probability 21, and the second driving plan 20B. The learner calculates a gradient for each of the internal parameters of the dynamic driving plan generator 400 by executing the error back propagation calculation using the loss value as a starting point.

In S1514, the learner adjusts the internal parameters of the dynamic driving plan generator 400 by executing back propagation calculation on the dynamic driving plan generator 400 using the gradient value.

In S1515, the learner determines whether one round of use of the data in the data set for learning is completed. When a result of the determination is false, the processing returns to S1502.

When the determination result in S1515 is true, the learner increments E_{c} by 1 in S1516.

In step S1517, the learner determines whether the updated E_{c} reaches a predetermined value. When a result of the determination is false, the processing returns to S1502. When the result of the determination is true, the learning of the dynamic driving plan generator 400 ends.

FIG. 16 shows an example of a flow of the cooperative learning between the compressor 200 and the decompressor 300, and the dynamic driving plan generator 400.

The flow is the same as the flow shown in FIG. 15 except that S1600 is executed between S1514 and S1515 in the flow shown in FIG. 15. That is, after the same processing as S1501 to S1514 is executed, S1600 is executed. In S1600, the learner updates the weights (internal parameters) of the compressor 200 and the decompressor 300 using the error back propagation method for the evaluation value generated based on the second driving plan 20B. After S1600, the same processing as S1515 to S1517 is executed.

In the processing shown in FIGS. 14 to 16, the compression, the reconstruction, and the reward calculation are executed. Examples of details of each of the compression, the reconstruction, and the reward calculation are as follows.

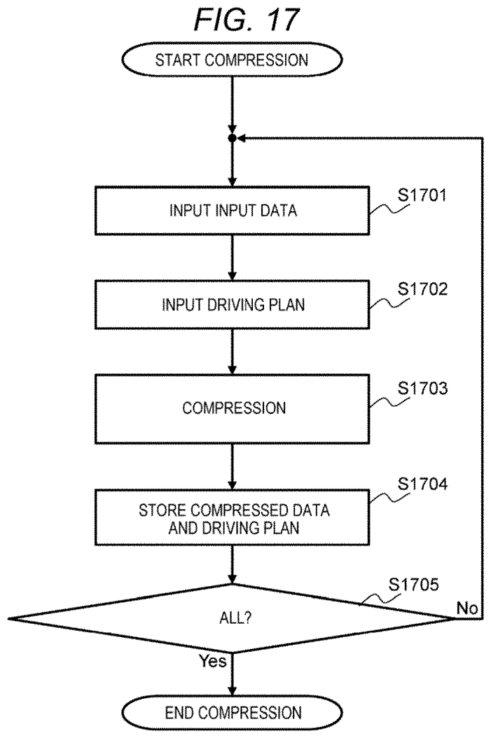

FIG. 17 shows an example of the compression flow.

In S1701, the input data 1000 is input to the compressor 200.

In S1702, the first driving plan 20A that is generated based on the input data 1000 input in S1701 is input to the compressor 200.

In S1703, the compressor 200 executes the partial driving (executes the forward propagation processing) according to the driving plan input in S1702, compresses the input data 1000, and outputs the compressed data 1100.

In S1704, for example, the CPU 3010 stores a set of the first driving plan 20A input in S1702 and the compressed data 1100 output in S1703 in a device of an output destination of the compressed data 1100, for example, in a storage device.

If input data to be compressed is still present (S1705: No), the processing returns to S1701.

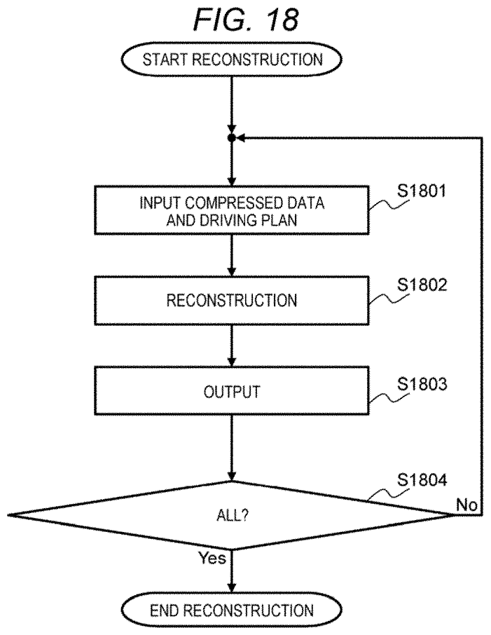

FIG. 18 shows an example of the reconstruction flow.

In S1801, for example, a set of the compressed data 1100 and the first driving plan 20A is read from the storage device by the CPU 3010, and the compressed data 1100 and the first driving plan 20A are input to the decompressor 300.

In S1802, the decompressor 300 executes the partial driving (executes the forward propagation processing) according to the input driving plan 20, reconstructs the compressed data 1100, and outputs the reconstructed data 1200.

In S1803, for example, the CPU 3010 outputs the reconstructed data 1200 to a device of an output destination, for example, to a display device.

If compressed data to be reconstructed is still present (S1804: No), the processing returns to S1801.

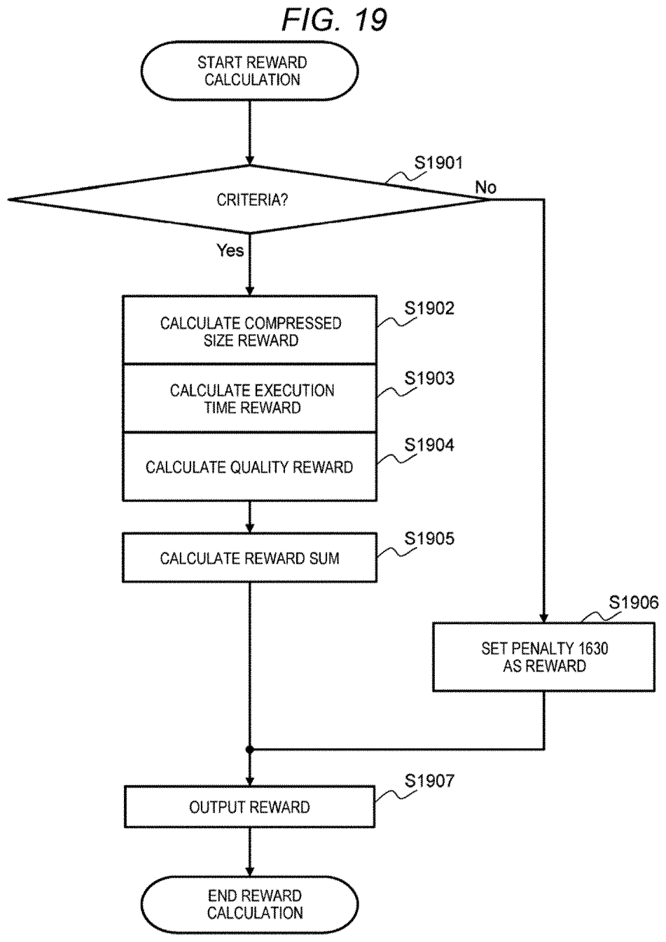

FIG. 19 shows an example of the reward calculation flow. In S1901, the driving plan 20 and a plurality of evaluation values (the compressed size 2100, the execution time 2110, and the quality 2120) corresponding to the driving plan are input to the reward calculator 500. The reward calculator 500 determines whether the evaluation value corresponding to the evaluation index that is represented by the priority 1650 and has the highest priority satisfies the criteria value represented by the criteria 1640.

If a determination result in S1901 is true, the following processing is executed. That is, in S1902, the reward calculator 500 calculates a compressed size reward that is a product of the compressed size 2100 and the weight W_{S} thereof. In S1903, the reward calculator 500 calculates an execution time reward that is a product of the execution time 2110 and the weight W_{T} thereof. In S1904, the reward calculator 500 calculates a quality reward that is a product of the quality 2120 and the weight W_{Q} thereof. In S1905, the reward calculator 500 calculates the reward 22 that is the sum of the compressed size reward, the execution time reward, and the quality reward. In S1907, the reward calculator 500 outputs the reward 22 calculated in S1905.

If the determination result in S1901 is false, the following processing is performed. That is, in S1906, the reward calculator 500 sets the penalty 1630 as the reward 22. In S1908, the reward calculator 500 outputs the reward 22 calculated in S1907.

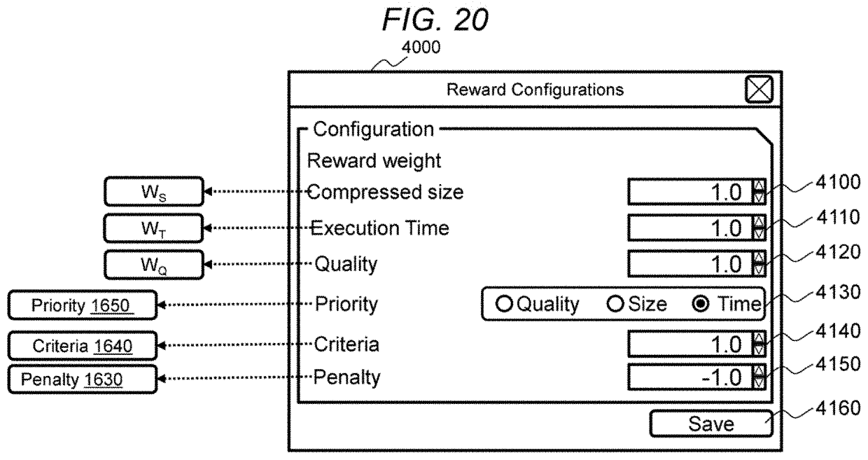

The weight, the priority 1650, the criteria 1640, and the penalty 1630 that are used in the reward calculation may be set via a user interface (UI), for example, before the start of the learning phase. For example, the processor 3010 may execute a predetermined program to display a setting screen 4000 shown in FIG. 20, for example, on the display device. The setting screen 4000 is a graphical user interface (GUI) and includes a plurality of GUI components. A GUI component 4100 is a UI that allows the weight W_{S} of the compressed size 2100 to be input. A GUI component 4110 is a UI that allows the weight W_{T} of the execution time 2110 to be input. A GUI component 4120 is a UI that allows the weight W_{Q} of the quality 2120 to be input. A GUI component 4130 is a UI that allows the evaluation index having the highest priority and recorded as the priority 1650 to be input. A GUI component 4140 is a UI that allows a criteria value recorded as the criteria 1640 to be input. A GUI component 4150 is a UI that allows a value of each bit constituting the penalty 1630 to be input. When information is input via these GUI components and a button “Save” 4160 is pressed, W_{S}, W_{T}, W_{Q}, the priority 1650, the criteria 1640, and the penalty 1630 are stored in, for example, the memory 3020.

As described above, in the learning phase, the processing shown in FIGS. 14 to 16 is performed. The details of the compression, the decompression, and the reward calculation in the processing are as shown in FIGS. 17 to 19. After the learning phase is ended, the inference phase is started. In the inference phase, for example, the following processing is performed.

That is, for example, the input data 1000, which is at least a part of write target data accompanying a write request, is input. An inference device, which is an example of a function implemented by the accelerator 3030 (or the CPU 3010), inputs the input data 1000 to the dynamic driving plan generator 400 to acquire the first driving plan 20A. The inference device inputs the input data 1000 and the driving plan 20 to the compressor 200 to acquire the compressed data 1100 from the partially driven compressor 200. The inference device outputs a set of the compressed data 1100 and the first driving plan 20A. The output set of the compressed data 1100 and the first driving plan 20A is stored by the CPU 3010 in, for example, a storage device that provides a region specified by the write request.

Thereafter, when a read request specifying the same region as the region is received, for example, the compressed data 1100 and the driving plan 20 are read from the storage device by the CPU 3010. The inference device inputs the compressed data 1100 and the driving plan 20 to the decompressor 300. The inference device acquires the reconstructed data 1200 from the partially driven decompressor 300, and outputs the reconstructed data 1200. The output reconstructed data 1200 is provided to a transmission source of the read request by, for example, the CPU 3010.

### Second Embodiment

A second embodiment will be described. At this time, differences from the first embodiment will be mainly described, and common points with the first embodiment will be omitted or simplified.

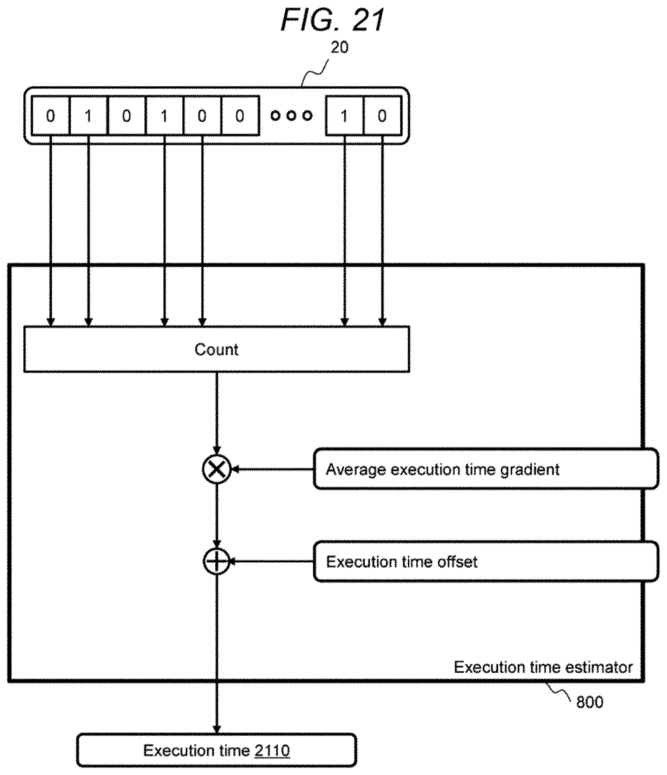

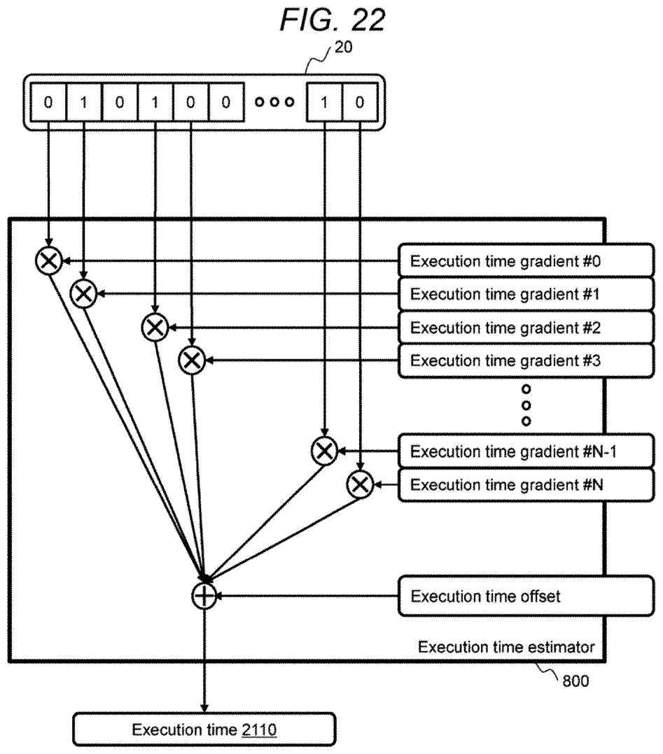

An execution time of compression and decompression is an actual measurement value in the first embodiment. However, the execution time is an estimation value in the second embodiment. Specifically, in the second embodiment, the information processing system 100 further includes an execution time estimator. The execution time estimator estimates the execution time based on the number of driving targets represented by the driving plan 20, that is, inputs the driving plan 20 and outputs the execution time 2110 as the estimation value. As a method for the execution time estimation, for example, both a first method shown in FIG. 21 and a second method shown in FIG. 22 can be adopted.

FIG. 21 shows the first method for the execution time estimation.

The first method for the execution time estimation is a method of using an average execution time coefficient for the entire driving plan 20. Specifically, the execution time estimator 800 counts the number of bits of the value “1” in the driving plan 20. The execution time estimator 800 calculates a value (for example, a product of the count value and the average execution time coefficient) in which the average execution time coefficient is reflected on a count value, and adds an execution time offset to the calculated value. The value after the addition is the execution time 2110. Information indicating the average execution time coefficient and the execution time offset is stored in, for example, the memory 3020.

FIG. 22 shows a second configuration example of the execution time estimation.

The second method for the execution time estimation is a method of using an individual execution time coefficient prepared for each bit constituting the driving plan 20 instead of the average execution time coefficient. Specifically, the execution time estimator 800 calculates, for each bit of the value “1” in the driving plan 20, a value (for example, a product of the execution time coefficient and the value “1”) in which the individual execution time coefficient corresponding to the bit is reflected in the value “1”. The execution time estimator 800 adds the execution time offset to a value (for example, the sum of all calculated values) based on the values. The value after the addition is the execution time 2110.

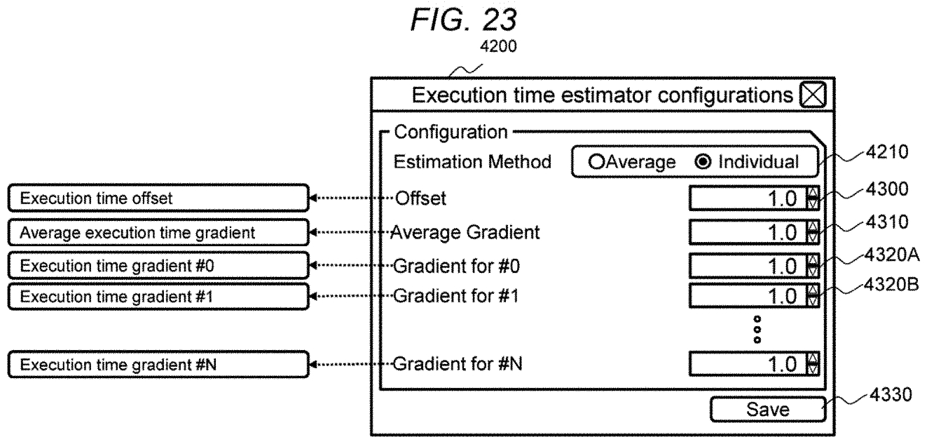

The execution time estimation method and the coefficient used in the execution time estimation may be set via the UI before the start of the learning phase, for example. For example, the processor 3010 may execute a predetermined program to display a setting screen 4200 shown in FIG. 23, for example, on the display device. The setting screen 4200 is a GUI and includes a plurality of GUI components. A GUI component 4210 is a UI that allows either “averaging” (the first method using the average execution time coefficient) or “individual” (the second method using the individual execution time coefficient) to be executed as the method for the execution time estimation. A GUI component 4300 is a UI that allows the execution time offset to be input. A GUI component 4310 is a UI that allows the average execution time coefficient to be input. Each of a plurality of GUI components 4320 is a UI that allows the individual execution time coefficient to be input. When information is input via the GUI components and the button “Save” 4330 is pressed, information indicating the method for the execution time estimation and the execution time coefficient is stored in, for example, the memory 3020. The execution time estimation method indicated by the stored information is executed by the execution time estimator 800. The average execution time coefficient may be an average of a plurality of individual execution time coefficients.

The above description of the first embodiment and the second embodiment can be summarized, for example, as follows.

The information processing system 100 includes the compressor 200, the decompressor 300, and the dynamic driving plan generator 400, which are NNs (an example of the machine learning model). The dynamic driving plan generator 400 generates the driving plan 20 representing a dynamic partial driving target of the compressor 200 and the decompressor 300 based on the input data 1000 input to the compressor 200. In the compressor 200 to which the input data 1000 and the driving plan 20 based on the input data 1000 are input, the partial compressor 700 to be driven represented by the driving plan 20 is driven to generate the compressed data 1100 of the input data 1000. In the decompressor 300 to which the compressed data 1100 and the driving plan 20 based on the input data 1000 corresponding to the compressed data 1100 are input, the partial decompressor 900 to be driven represented by the driving plan 20 is driven to generate the reconstructed data 1200 of the compressed data 1100. The dynamic driving plan generator 400 has already been learned in the learning phase based on the plurality of evaluation values obtained for the driving plan 20. Each of the plurality of evaluation values corresponds to a respective one of a plurality of evaluation indexes for the driving plan 20, and the plurality of evaluation values are a plurality of values obtained when at least the compression of the compression and the reconstruction according to the driving plan 20 is executed. The plurality of evaluation indexes include an execution time for one or both of the compression and the reconstruction of the data. That is, in the above-described embodiments, the execution time is the execution time of the compression and the reconstruction, but may be the execution time of one of the compression and the reconstruction instead.

The learning of the dynamic driving plan generator 400 that generates the driving plan 20 for partially driving at least one of the compressor 200 and the decompressor 300 is executed based on the gradient calculated from the loss value based on the reward delta 2202. The first reward 22A and the second reward 22B, which are the basis of the reward delta 2202, are determined based on the plurality of evaluation values obtained when at least the compression of the compression and the reconstruction according to the driving plan 20 is executed corresponding to the plurality of evaluation indexes. The plurality of evaluation values include an execution time for one or both of the compression and the reconstruction of the data. Accordingly, the execution time can be appropriately reduced.

In the learning phase, the processor may determine the reward based on the plurality of evaluation values of the driving plan 20 generated based on the input data 1000 input to the compressor 200. A processor (for example, a learner) may adjust the internal parameters of the dynamic driving plan generator 400 based on the reward. In this way, it can be expected to prepare the dynamic driving plan generator 400 capable of generating the optimal driving plan 20A from the viewpoint of reducing the execution time.

In the learning phase, the dynamic driving plan generator 400 may generate the driving probability 21 including the probability of each of the plurality of elements related to the compressor 200 based on the input data 1000 of the compressor 200. The dynamic driving plan generator 400 may generate the first driving plan 20A used in the inference phase as a reference system based on the driving probability 21, and may generate one or more second driving plans 21B based on the driving probability 21. The processor may determine the first reward 22A based on a plurality of evaluation values for the first driving plan 20A. The processor may determine the second reward 22B based on the second driving plan 21B for each of the one or more second driving plans 21B, calculate the reward delta 2202 between the first reward 22A and the second reward 22B, calculate the loss value based on the second driving plan 20B, the driving probability 21, and the calculated reward delta, and calculate the gradient by executing the error back propagation calculation based on the loss value. The processor may adjust the internal parameters of the dynamic driving plan generator 400 based on the gradient calculated for each of the one or more second driving plans 20B. In this manner, the two driving plans 20A and 20B are generated based on the same input data 1000. The reward delta 2202 which is the delta between the rewards 22A and 22B corresponding to the driving plans 20A and 20B is calculated. Then, the loss value is calculated based on the reward delta 2202, and the dynamic driving plan generator 400 is learned based on the gradient obtained based on the loss value. Therefore, it can be expected to prepare the dynamic driving plan generator 400 capable of generating the optimal driving plan 20 from the viewpoint of reducing the execution time. Specifically, for example, processing is as follows. That is, in the learning of the dynamic driving plan generator 400, the same external condition is set, the appropriate driving plan 20A and the slightly changed driving plan 20B (for example, a part of the driving plan 20A is changed) are executed, and the driving plan 20A is adjusted according to whether a relative result is good or bad. When the result is relatively good by slightly changing the driving plan 20A, the internal parameters of the dynamic driving plan generator 400 are corrected so that the driving plan 20A is close to the driving plan 20B after the change. On the other hand, when the result is relatively bad, the correction in a reverse direction is executed. By generating and comparing the driving plans 20A and 20B, an adjustment direction can be determined based on the delta.

The plurality of evaluation values may include the quality 2120 based on the delta between the input data 1000 and the reconstructed data 1200 corresponding to the input data 1000. The processor (for example, the learner) may adjust the internal parameters of the compressor 200 and the decompressor 300 based on the compression quality based on the delta between the input data 1000 input in the learning of the compressor 200 and the decompressor 300 and the reconstructed data 1200 corresponding to the input data 1000. The processor (for example, the learner) may adjust the internal parameters of the dynamic driving plan generator 400 based on the execution time 2110 and the quality 2120 corresponding to the driving plan 20. In this way, the element which is the compression quality used for the learning of the compressor 200 and the decompressor 300 is also used for the learning of the dynamic driving plan generator 400. Therefore, it can be expected to prepare the dynamic driving plan generator 400 suitable for the compressor 200 and the decompressor 300.

In the learning phase, learning of the compressor 200 and the decompressor 300 is executed. Then, learning of the dynamic driving plan generator 400 is executed. Then, cooperative learning (that is, the learning of the dynamic driving plan generator 400 and the learning of the compressor 200 and the decompressor 300 that are driven according to the driving plan 20 generated by the dynamic driving plan generator 400) is executed. By executing the learning in such an order, optimization of each of the compressor 200, the decompressor 300, and the dynamic driving plan generator 400 can be expected. Specifically, for example, processing is as follows. That is, when the compressor 200 and the decompressor 300, which are constituted by the NN in a state of being initialized by, for example, a random number, start the partial driving, only the execution time acts as a reliable loss term in the learning of the compressor 200 and the decompressor 300 that only output a reconstructed image such as noise. As a result, it is considered that the learning is executed so that all values of the driving plan 20 are set to “0”. In this case, even if the execution time becomes the shortest, a compression and reconstruction result does not become the expected result. Therefore, as the learning of a first stage, only the compressor 200 and the decompressor 300 are learned (in the learning, each value of the driving plan 20 is set to “1”). As the learning in a second stage, trial of stopping the partial NN considered to be unnecessary is repeated for each piece of the input data 1000, and the portion having little influence is turned off (non-driving target). The dynamic driving plan generator 400 outputs the driving plan 20 having low quality immediately after the initialization by the random number. Therefore, when the above-described cooperative learning is executed in the learning in the second stage, the compressor 200 and the decompressor 300 maybe adversely affected. Therefore, in the learning in the second stage, only the dynamic driving plan generator 400 is learned. Finally, as the learning in a third stage, the cooperative learning of matching is executed in a state in which both (the compressor 200 (the decompressor 300) and the dynamic driving plan generator 400) are sufficiently learned.

The input data 1000 may be multidimensional data (for example, image data). Accordingly, it is possible to provide a system in which the execution time of the compression and the reconstruction of the multidimensional data is reduced.

Each of the plurality of partial compressors 700 may include the plurality of data paths 73 and the mixer 740 that outputs data based on data flowing through the plurality of data paths 73A to 73C. The plurality of data paths 73 may include the skip path 73A and two or more compression paths (for example, 73B and 73C). The skip path 73A may be a data path that does not pass through any of the compression functional blocks. The two or more compression paths (for example, 73B or 73C) maybe two or more data paths each passing through a respective one of two or more compression functional blocks that execute compression of different compression qualities. The compression functional block may be a functional block that executes the compression. The driving plan 20 may represent a driving content including which compression functional block of the partial compressor 700 to be driven is to be driven. Accordingly, detailed partial driving is possible. Therefore, an appropriate balance can be achieved in which reduction of the execution time and improvement of the evaluation value of another evaluation index are compatible. For example, most of a part of the partial compressors 700 to be driven in the compressor 200 execute compression with low compression quality and low calculation load, and a part of the partial compressors 700 executes compression with high compression quality and high calculation load. Therefore, it can be expected that the balance between the compression quality and the execution time is compatible. As the compression functional block, a residual block or a convolution layer may be adopted.

In each of the plurality of partial compressors, the compression corresponding to at least one compression functional block may be irreversible compression. Therefore, a large amount of data such as the multidimensional data or time-series data can be expected to be compressed and stored with high efficiency.

The reward 22 may be a reward based on a plurality of evaluation values and a plurality of weights each corresponding to a respective one of a plurality of evaluation indexes. Accordingly, optimization of the reward given to the dynamic driving plan generator 400 can be expected. Therefore, the optimization of the dynamic driving plan generator 400 can be expected. For example, when the evaluation value of the evaluation index having the highest priority satisfies a criteria value, a reward based on a plurality of evaluation values may be determined. Therefore, by adjusting the plurality of weights, it can be expected to prepare the dynamic driving plan generator 400 that generates the driving plan 20 for improving other evaluation values (for example, the quality 2120) within a range. In the range, the evaluation value (for example, the execution time 2110) of any evaluation index having the highest priority satisfies the criteria value.

The processor (for example, the execution time estimator 800) may estimate the execution time 2110 based on the number of the partial driving targets represented by the driving plan 20. Accordingly, the load can be reduced as compared with the actual measurement of the execution time. The processor (for example, the execution time estimator 800) may estimate the execution time 2110 using a common coefficient (for example, an average execution time coefficient) regardless of which one the driving plan 20 sets as the partial driving target. Accordingly, the execution time 2110 can be estimated at a high speed. On the other hand, the processor (for example, the execution time estimator 800) may estimate the execution time 2110 using one or more individual coefficients (individual execution time coefficients) each corresponding to a respective one of one or more partial driving targets represented by the driving plan 20. Accordingly, it can be expected that estimation accuracy of the execution time 2110 is high.

Although some embodiments are described above, the embodiments are examples for describing the invention, and are not intended to limit the scope of the invention to these embodiments. The invention can be implemented in various other forms.

What is claimed is:

1. An information processing system comprising:
an interface device for one or more input and output devices; and
a processor that controls data input and output via the interface device, wherein
each of a compressor that is executed by the processor and includes a plurality of partial compressors, a decompressor that is executed by the processor and includes a plurality of partial decompressors, and a dynamic driving plan generator that is executed by the processor is a machine learning model,
the dynamic driving plan generator generates a driving plan representing a dynamic partial driving target of the compressor and the decompressor based on input data input to the compressor,
in the compressor to which the input data and the driving plan based on the input data are input, a partial compressor to be driven represented by the driving plan is driven to generate compressed data of the input data,
in the decompressor to which the compressed data and the driving plan based on the input data corresponding to the compressed data are input, a partial decompressor to be driven represented by the driving plan is driven to generate reconstructed data of the compressed data,
the dynamic driving plan generator has already been learned in a learning phase based on a plurality of evaluation values obtained for the driving plan,
each of the plurality of evaluation values corresponds to a respective one of a plurality of evaluation indexes for the driving plan, and the plurality of evaluation values are a plurality of values obtained when at least the compression of the compression and the reconstruction according to the driving plan is executed, and
the plurality of evaluation indexes include an execution time for one or both of the compression and the reconstruction of data.

2. The information processing system according to claim 1, wherein
in the learning phase,
the processor determines a reward based on the plurality of evaluation values of the driving plan generated based on the input data input to the compressor, and
the processor adjusts an internal parameter of the dynamic driving plan generator based on the reward.

3. The information processing system according to claim 2, wherein
in the learning phase,
the dynamic driving plan generator
generates a driving probability including a probability of each of a plurality of elements related to the compressor based on the input data of the compressor,
generates a first driving plan used in an inference phase as a reference system based on the driving probability,
generates one or more second driving plans based on the driving probability, and
the processor
determines a first reward based on a plurality of evaluation values for the first driving plan,
determines, a second reward based on a plurality of evaluation values for the second driving plan for each of the one or more second driving plans, calculates a reward delta that is a delta between the first reward and the second reward, calculates a loss value based on the second driving plan, the driving probability, and the calculated reward delta, and calculates a gradient by executing error back propagation calculation based on the loss value, and
adjusts an internal parameter of the dynamic driving plan generator based on the gradient calculated for each of the one or more second driving plans.

4. The information processing system according to claim 1, wherein
the plurality of evaluation values include compression quality based on a delta between the input data and reconstructed data corresponding to the input data, and
in the learning phase,
the processor adjusts an internal parameter of each of the compressor and the decompressor based on the compression quality based on the delta between the input data and the reconstructed data corresponding to the input data, and
the processor adjusts an internal parameter of the dynamic driving plan generator based on a reward based on the execution time and the compression quality that correspond to the driving plan.

5. The information processing system according to claim 1, wherein
in the learning phase,
learning of the compressor and the decompressor is executed,
learning of the dynamic driving plan generator is then executed, and
thereafter, learning of the compressor and the decompressor that are driven according to the driving plan generated by the dynamic driving plan generator is executed.

6. The information processing system according to claim 1, wherein
the input data is multidimensional data.

7. The information processing system according to claim 1, wherein
each of the plurality of partial compressors includes a plurality of data paths and a mixer that outputs data based on data flowing through the plurality of data paths,
the plurality of data paths are one or more compression paths which are one or more data paths passing through one or more compression functional blocks, and a skip path which is a data path not passing through any of the compression functional blocks,
each of the compression functional blocks is a functional block that executes compression, and
the driving plan represents a driving content including which compression functional block of the partial compressor to be driven is to be driven for the partial compressor.

8. The information processing system according to claim 1, wherein
in each of the plurality of partial compressors, the compression corresponding to at least one compression functional block is irreversible compression.

9. The information processing system according to claim 2, wherein
the determined reward is a reward based on the plurality of evaluation values and a plurality of weights each corresponding to a respective one of the plurality of evaluation indexes.

10. The information processing system according to claim 9, wherein
a reward based on the plurality of evaluation values is determined when the evaluation value of the evaluation index having a highest priority satisfies a criteria value.

11. The information processing system according to claim 1, wherein
the processor estimates the execution time based on the number of partial driving targets represented by the driving plan, and
the execution time included in the plurality of evaluation values is the estimated execution time.

12. The information processing system according to claim 11, wherein
the processor estimates the execution time using a common coefficient regardless of which one the driving plan sets as the partial driving target.

13. The information processing system according to claim 11, wherein
the processor estimates the execution time using one or more individual coefficients each corresponding to a respective one of one or more partial driving targets represented by the driving plan.

14. A compression control method comprising:
generating, by a dynamic driving plan generator that is a machine learning model, a driving plan representing a dynamic partial driving target of a compressor that is a machine learning model and includes a plurality of partial compressors and a decompressor that is a machine learning model and includes a plurality of partial decompressors, based on input data input to the compressor;
generating compressed data of the input data by driving a partial compressor to be driven represented by the driving plan in the compressor to which the input data and the driving plan based on the input data are input; and
generating reconstructed data of the compressed data by driving a partial decompressor to be driven represented by the driving plan in the decompressor to which the compressed data and the driving plan based on the input data corresponding to the compressed data are input, wherein
the dynamic driving plan generator has already been learned in a learning phase based on a plurality of evaluation values obtained for the driving plan,
each of the plurality of evaluation values corresponds to a respective one of a plurality of evaluation indexes for the driving plan, and the plurality of evaluation values are a plurality of values obtained when at least the compression of the compression and the reconstruction according to the driving plan is executed, and
the plurality of evaluation indexes include an execution time for one or both of the compression and the reconstruction of data.
